(19) United States
(12) Patent Application Publication
(10) Pub. No.: US 2026/0190487 A1
(43) Pub. Date: Jul. 2, 2026

(54) DISPLAY PANEL AND DISPLAY DEVICE

(71) Applicant: Xiamen Tianma Display Technology Co., Ltd., Xiamen (CN)

(72) Inventors: Huomei HUA, Xiamen (CN); Huangyao Wu, Xiamen (CN)

(73) Assignee: Xiamen Tianma Display Technology Co., Ltd., Xiamen (CN)

(21) Appl. No.: 19/242,939

(22) Filed: Jun. 18, 2025

(30) Foreign Application Priority Data
Dec. 31, 2024 (CN) 202411997474.8

(51) Int. Cl. H10D 86/40

(52) U.S. Cl. CPC H10D 86/441

(57) ABSTRACT

A display panel and a display device are disclosed in the present application. The display panel includes a display area and a non-display area, the non-display area comprises a first functional area, a trace area, and a second functional area that are sequentially closer and closer to the display area in a first direction; the trace area comprises a plurality of first traces, at least part of the first traces each comprise a first conductive portion and a second conductive portion, a first end of the first conductive portion is electrically connected to an output end of the first functional area, a second end of the first conductive portion is electrically connected to a first end of the second conductive portion, a second end of the second conductive portion is electrically connected to an input end of the second functional area.

### CROSS-REFERENCE TO RELATED APPLICATIONS

This application claims priority to Chinese Patent Application No. 202411997474.8, titled “DISPLAY PANEL AND DISPLAY DEVICE” and filed on Dec. 31, 2024, which is hereby incorporated by reference in its entirety.

### TECHNICAL FIELD

The present application relates to the field of display technology, and in particular to a display panel and a display device.

### BACKGROUND

With the development of display technology, the application of display panels is becoming more and more common. The display panel includes a display area, in which sub-pixels and data lines are disposed. On least one side of the display area, there is a disposed non-display area, in which a driver chip, some functional areas, a trace area, etc. are disposed, and traces are disposed in the trace area. The traces in the trace area are electrically connected to the driver chip and the data lines for transmitting the data signal provided by the driver chip to the data lines.

How to optimize the traces of the trace area is an important problem faced by those skilled in the art.

### SUMMARY

The embodiments of the present application provide a display panel and a display device, which can optimize the trace design in the trace area.

In a first aspect, the embodiments of the present application provide a display panel, which includes a display area and a non-display area, the non-display area comprises a first functional area, a trace area, and a second functional area that are sequentially closer and closer to the display area in a first direction; the trace area comprises a plurality of first traces, at least part of the first traces each comprise a first conductive portion and a second conductive portion, a first end of the first conductive portion is electrically connected to an output end of the first functional area, a second end of the first conductive portion is electrically connected to a first end of the second conductive portion, a second end of the second conductive portion is electrically connected to an input end of the second functional area, and the first conductive portion and the second conductive portion are located in different film layers.

In a second aspect, the embodiments of the present application provide a display device, including the display panel as described in the embodiments of the first aspect.

According to the display panel and the display device provided by the embodiments of the present application, the first trace in the trace area includes a first conductive portion and a second conductive portion, and the first conductive portion and the second conductive portion are located in different film layers, that is, the first trace is no longer limited to the same film layer, so that the trace form of the first trace can be more flexibly designed to optimize the trace design in the trace area.

### BRIEF DESCRIPTION OF THE DRAWINGS

Other features, purposes and advantages of the present application will be more apparent by reading the following detailed description of the non-restrictive embodiments with reference to the drawings. Here, the same or similar reference numerals indicate the same or similar features, and the drawings are not drawn to actual scale.

FIG. 1 shows a schematic structural diagram of a display panel provided in an embodiment of the present application;

FIG. 2 shows a wiring schematic diagram of a local area of the display panel provided in an embodiment of the present application;

FIG. 3 shows a schematic structural diagram of a layout of the area C1 in FIG. 2;

FIG. 4 shows a wiring schematic diagram of a local area of a display panel in a comparative example;

FIG. 5 shows another wiring schematic diagram of a local area of a display panel provided in an embodiment of the present application;

FIG. 6 shows a schematic structural diagram of a layout of the area C2 in FIG. 5;

FIG. 7 shows another wiring schematic diagram of a local area of a display panel provided in an embodiment of the present application;

FIG. 8 shows a schematic structural diagram of a layout of the area C3 in FIG. 7.

FIG. 9 shows another wiring schematic diagram of a local area of a display panel provided in an embodiment of the present application;

FIG. 10 shows another wiring schematic diagram of a local area of a display panel provided in an embodiment of the present application;

FIG. 11 shows another schematic structural diagram of a display panel provided in an embodiment of the present application;

FIG. 12 shows a schematic structural diagram of a test circuit in a display panel provided in an embodiment of the present application;

FIG. 13 shows another wiring schematic diagram of a local area of a display panel provided in an embodiment of the present application;

FIG. 14 shows a schematic structural diagram of a film layer of a display panel provided in an embodiment of the present application;

FIG. 15 shows a schematic structural diagram of another film layer of a display panel provided in an embodiment of the present application; and

FIG. 16 shows a schematic structural diagram of a display device provided in an embodiment of the present application.

### DETAILED DESCRIPTION

The features and exemplary embodiments of various aspects of the present application will be described in detail below. In order to make the purpose, technical solutions and advantages of the present application clearer, the present application will be further described in detail below in conjunction with the drawings and specific embodiments. It should be understood that the specific embodiments described herein are only configured to explain the present application and are not configured to limit the present application. For those skilled in the art, the present application can be implemented without some of these specific details. The following description of the embodiments is only to provide a better understanding of the present application by showing examples of the present application.

It should be noted that in the present application, relational terms such as first and second are only used to distinguish one entity or operation from another entity or operation, and do not necessarily require or imply any such actual relationship or order between these entities or operations. Moreover, the terms “include”, “comprise” or any other variant thereof are intended to cover non-exclusive inclusion, so that a process, method, article or device including a series of elements includes not only those elements, but also other elements not explicitly listed, or also includes elements inherent to such a process, method, article or device. In the absence of further restrictions, the elements defined by the sentence “include . . . ” do not exclude the existence of other identical elements in the process, method, article or device including the elements.

It should be understood that when describing the structure of a component, when a layer or a region is referred to as being “above” or “on” another layer or another region, the layer or region may refer to being directly above another layer or another region, or including other layers or regions between the layer or region and another layer or another region. Moreover, if the component is turned over, the layer or region will be “below” or “under” another layer or another region.

It should be understood that the term “and/or” used in the present application is only a description of the association relationship of the associated objects, indicating that there may be three relationships, for example, A and/or B may represent three situations: A exists alone, A and B exist at the same time, and B exists alone. In addition, the character “/” in the present application generally indicates that the previous and next associated objects are in an “or” relationship.

In the embodiments of the present application, the term “electrically connected” may refer to a direct electrical connection between two components, or may refer to an electrical connection between two components via one or more other components. The term “portion” may refer to a “local part”. The term “end” may refer to an “end segment” or an “end edge”. The display panel may be a display device or a module/part of a display device.

It is obvious to those skilled in the art that various modifications and changes can be performed in the present application without departing from the gist or scope of the present application. Therefore, the present application is intended to cover modifications and changes of the present application that fall within the scope of the corresponding claims (technical solutions claimed for protection) and their equivalents. It should be noted that the implementation methods provided in the embodiments of the present application can be combined with one another without contradiction.

The embodiments of the present application provide a display panel and a display device. Various embodiments of the display panel and the display device will be described below with reference to the drawings.

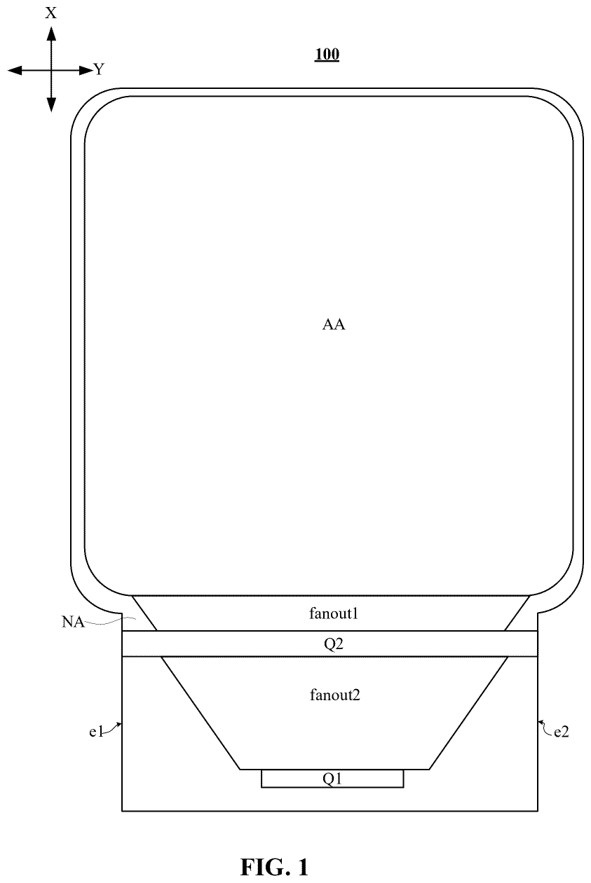

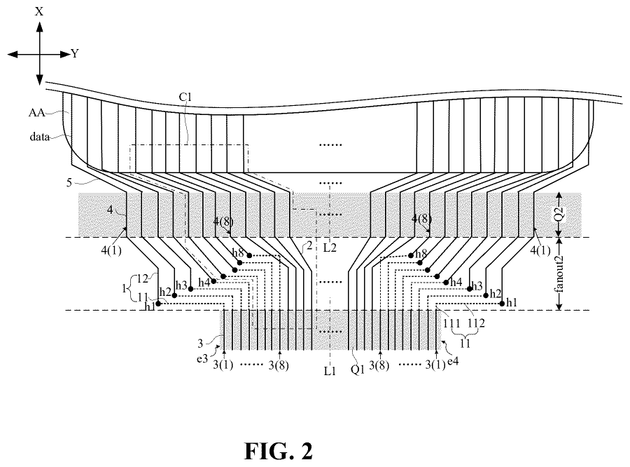

FIG. 1 shows a schematic structural diagram of a display panel provided by an embodiment of the present application. FIG. 2 shows a wiring schematic diagram of a local area of a display panel provided by an embodiment of the present application. Referring to FIG. 1 and FIG. 2 in combination, the display panel 100 provided by an embodiment of the present application includes a display area AA and a non-display area NA. The non-display area NA includes a first functional area Q1, a trace area fanout2, and a second functional area Q2 that are adjacent to the display area AA along the first direction X in sequence. In other words, in the first direction X, the trace area fanout2 is located between the first functional area Q1 and the second functional area Q2, and the second functional area Q2 is located between the display area AA and the trace area fanout2.

The trace area fanout2 includes a plurality of first traces 1, and at least part of the first traces 1 each include a first conductive portion 11 and a second conductive portion 12. The first end of the first conductive portion 11 is electrically connected to the output end of the first functional area Q1, the second end of the first conductive portion 11 is electrically connected to the first end of the second conductive portion 12, the second end of the second conductive portion 12 is electrically connected to the input end of the second functional area Q2, and the first conductive portion 11 and the second conductive portion 12 are located in different film layers.

In some embodiments, the second functional area Q2 and the display area AA are provided with a first fanout area fanout1 therebetween. A driver chip IC is disposed at the side of the first functional area Q1 away from the trace area fanout2, and the first functional area Q1 is electrically connected to the driver chip IC.

Exemplarily, the first functional area Q1 includes a third trace 3, the first end of the third trace 3 is electrically connected to the data signal output end of the driver chip IC, and the second end of the third trace 3 is electrically connected to the first end of the first conductive portion 11. The second end of the third trace 3 is the output end of the first functional area Q1.

The second functional area Q2 includes a fourth trace 4, and the first fanout area fanout1 includes a fifth trace 5, the first end of the fourth trace 4 is electrically connected to the second end of the second conductive portion 12, and the second end of the fourth trace 4 is electrically connected to the first end of the fifth trace 5. The first end of the fourth trace 4 is the input end of the second functional area Q2.

The second end of the fifth trace 5 is electrically connected to the data line data.

The driver chip IC is electrically connected to the third trace 3, and the data signal provided by the data signal output end of the driver chip IC is transmitted to the data line data via the third trace 3, the first trace 1, the fourth trace 4, and the fifth trace 5 in sequence.

It should be noted that, in order to facilitate the distinction between the first conductive portion 11 and the second conductive portion 12, the first conductive portion 11 is indicated by a dotted line and the second conductive portion 12 is indicated by a solid line in the wiring schematic diagram of the present application. In addition, the area filled with gray in the wiring schematic diagram of the present application represents the first functional area Q1 and the second functional area Q2.

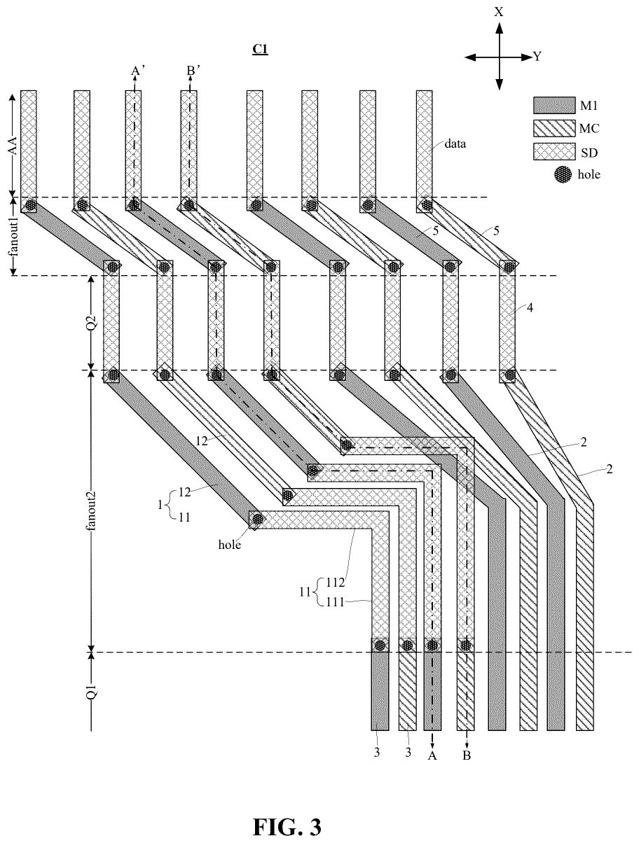

Exemplarily, as shown in FIG. 3, the graphics with the same filling pattern in FIG. 3 represent structures located in the same film layer, and the graphics with different filling patterns represent structures located in different film layers. FIG. 3 illustrates the first metal layer M1, the capacitor metal layer MC, and the source-drain metal layer SD. The first metal layer M1, the capacitor metal layer MC, and the source-drain metal layer SD are different metal film layers. For example, the first conductive portion 11 is located in the source-drain metal layer SD, some second conductive portions 12 are located in the first metal layer M1, and other second conductive portions 12 are located in the capacitor metal layer MC. It is understandable that the first conductive portion 11 and the second conductive portion 12 are located in different film layers, and the two are connected by a connection hole hole. It should be noted that although the fourth trace 4 and the first conductive portion 11 are located in the same film layer in each layout of the present application, which is not used to limit the present application. For example, in other examples, the fourth trace 4 and the first conductive portion 11 are located in different film layers.

According to the display panel provided in the embodiments of the present application, the first trace in the trace area includes a first conductive portion and a second conductive portion, and the first conductive portion and the second conductive portion are located in different film layers, that is, the first trace is no longer limited to the same film layer, so that the trace form of the first trace can be more flexibly designed to optimize the trace design in the trace area.

With the development of display technology, large-size display panels have emerged. The larger the size of the display panel is, the more sub-pixels are, and the more data lines are required. Correspondingly, the number of traces in the trace area is also more, so that the trace area requires a certain height to arrange a large number of traces, and the space occupied by the trace area in the first direction increases.

In view of this, referring to FIG. 1 and FIG. 2 in combination, in the second direction Y, the second end of at least one first conductive portion 11 is closer to the edge of the display panel than the first functional area Q1 is, and the first direction X and the second direction Y intersect with each other. For example, the second direction Y is the arrangement direction of the plurality of third traces 3 in the first functional area Q1.

It should be noted that the recitation that the second end of at least one first conductive portion 11 is closer to the edge of the display panel than the first functional area Q1 is, which applies to the area at any one side of the first center line L1 in the second direction Y. The first center line L1 is the center line of the first functional area Q1 extending along the first direction X. The distance between the first center line L1 and the edge e3 is equal to the distance between the first center line L1 and the edge e4. The edge e3 and the edge e4 are two opposite edges of the first functional area Q1 in the first direction X.

It should also be noted that the first center line in the present application and the second center line mentioned later do not represent any real lines existing in the display panel. The center line can be understood a virtually defined position center line, that is, the center line is used to indicate the position. In addition, in the present application, two or more parameters defined to be “equal”, “equal to”, and “=” may not be absolutely equal, and a certain error is allowed. It should be noted that the equal distance mentioned in the present disclosure refers to the distance value being equal within the allowable error range (±5%).

Exemplarily, the display panel includes a first edge e1 and a second edge e2 opposite to each other in the second direction Y, and the first functional area Q1 includes a third edge e3 and a fourth edge e4 opposite to each other in the second direction Y. The first edge e1 and the third edge e3 are at the first side of the first center line L1, and the second edge e2 and the fourth edge e4 are at the second side of the first center line L1.

For the first side of the first center line L1, the second end of at least one first conductive portion 11 is closer to the first edge e1 than the third edge e3 of the first functional area Q1 is.

For the second side of the first center line L1, the second end of at least one first conductive portion 11 is closer to the second edge e2 than the fourth edge e4 of the first functional area Q1 is.

In FIG. 2, solid black dots are used to indicate the connection hole between the first conductive portion 11 and the second conductive portion 12. For example, the first side and the second side of the first center line L1 each are provided with 8 first traces 1, and the 8 first traces 1 each include a first conductive portion 11 and a second conductive portion 12, and the first side and the second side of the first center line L1 each are provided with the 8 connection holes, which are marked as h1-h8 respectively. For any first trace 1, the second end of the first conductive portion 11 overlaps the connection hole in the thickness direction of the display panel. That is, in FIG. 2, the position of the second end of the first conductive portion 11 is the same as the position of the connection hole. At the first side of the first center line L1, the connection holes h1-h4 are closer to the first edge e1 than the third edge e3 is; at the second side of the first center line L1, the connection holes h1-h4 are closer to the second edge e2 than the fourth edge e4 is. That is to say, in this embodiments, at least part of the connection holes of the first conductive portion 11 and the second conductive portion 12 are moved to both sides of the first functional area Q1 in the second direction Y.

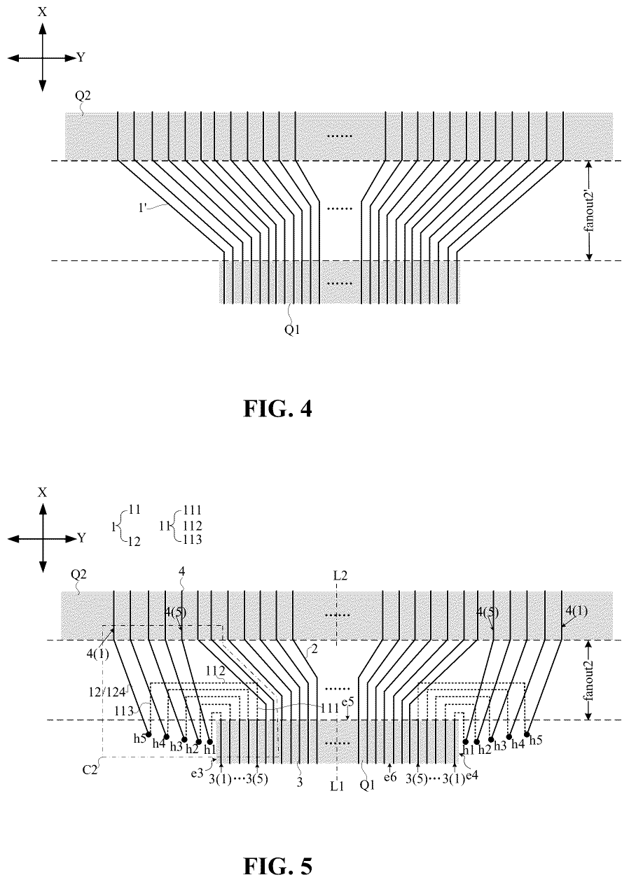

In order to better understand the beneficial effects of the embodiments of the present application, referring to FIG. 4 for comparison, in FIG. 4, the multiple traces 1′in the trace area fanout2′ are arranged in a fan-shaped manner as a whole.

In the second direction Y, the width of the first functional area Q1 is smaller than the width of the second functional area Q2. In some examples, the width of the first functional area Q1 is much smaller than the width of the second functional area Q2. When the trace 1′extends from the second functional area Q2 toward the first functional area Q1, the trace 1′needs to run closer to the center of the first functional area Q1. In order to avoid cross-circuiting between the traces 1′, the height of the trace area fanout2′ in the first direction X needs to be increased in FIG. 4, resulting in a relatively large height of the trace area fanout2′ in the first direction X.

In the embodiments of the present application, the connection position of the first conductive portion 11 and the second conductive portion 12 in at least part of the first traces is designed to be closer to the edge, which is equivalent to widening the width of the trace area fanout2 in the second direction Y, and increasing the arrangement space of the traces in the trace area fanout2 in the second direction Y. In this way, the height of the trace area fanout2 in the first direction X can be reduced, thereby reducing the space occupied by the trace area fanout2 in the first direction X.

Exemplarily, the space saved by the trace area fanout2 in the first direction X can be used to place other structures of the display panel, such as placing a battery structure.

In some embodiments, as shown in FIG. 2, the first conductive portion 11 includes at least a first segment 111 and a second segment 112, and the second segment 112 is electrically connected between the first segment 111 and the second conductive portion 12. In the second direction Y, in the same first trace 1, the first segment 111 and the second segment 112 are closer to the first center line L1 of the first functional area Q1 than the second conductive portion 12 is.

For example, at the first side of the first center line L1, in the second direction Y, in any one first trace 1, the first segment 111 and the second segment 112 are located at the side of the second conductive portion 12 close to the first center line L1.

For another example, at the second side of the first center line L1, in the second direction Y, in any one first trace 1, the first segment 111 and the second segment 112 are located at the side of the second conductive portion 12 close to the first center line L1.

As described above, the second end of at least one first conductive portion 11 is closer to the edge of the display panel than the first functional area Q1 is. In the second direction Y, the first segment 111 and the second segment 112 are closer to the first center line L1 of the first functional area Q1 than the second conductive portion 12 is, which can ensure that at least part of the second conductive portions 12 do not need to extend to the area directly opposite to the first functional area Q1 in the first direction X. In other words, at least part of the second conductive portions 12 are offset from the first functional area Q1 in the first direction X. These second conductive portions 12 are arranged at both sides of the first functional area Q1 in the second direction Y, thereby ensuring that the arrangement space of the traces in the trace area fanout2 in the second direction Y can be increased and the height of the trace area fanout2 in the first direction X can be reduced.

Exemplarily, referring to FIG. 2 and FIG. 4 for comparison, the wiring pattern in the trace area fanout2 in FIG. 2 is different from the wiring pattern in the trace area fanout2′ in FIG. 4, while the structures of other areas are the same. The height of the trace area fanout2′ in FIG. 4 in the first direction X is about 9500 μm, while the height of the trace area fanout2 in FIG. 2 in the first direction X can be compressed to about 5000 μm.

In some embodiments, the first segment 111 and the second segment 112 are located in the same film layer.

It is understandable that the first segment 111 and the second conductive portion 12 are located in different film layers, and the second segment 112 and the second conductive portion 12 are located in different film layers. For example, as shown in FIG. 3, the first segment 111 and the second segment 112 are located in the source-drain metal layer SD, some second conductive portions 12 are located in the first metal layer M1, and other second conductive portions 12 are located in the capacitor metal layer MC.

In this embodiment, the first segment 111 and the second segment 112 are designed in the same film layer, and the first segment 111 and the second segment 112 do not need to be connected through a connection hole, which can reduce the occupied space; in addition, the first segment 111 and the second segment 112 can be prepared in an integrated manner to simplify the process.

In some embodiments, as shown in FIG. 2 or FIG. 3, the first segment 111 extends along the first direction X, and the second segment 112 extends along the second direction Y. The second segment 112 is located at the side of the first segment 111 away from the first center line L1. The first segment 111 and the second segment 112 together constitute the first conductive portion 11 in a shape of “right-angled polygonal line”, so that the first end of the second conductive portion 12 at the first side of the first center line L1 moves along the direction close to the first edge e1, and the first end of the second conductive portion 12 at the second side of the first center line L1 moves along the direction close to the second edge e2, thereby increasing the trace arrangement space of the trace area fanout2 in the second direction Y, so as to reduce the height of the trace area fanout2 in the first direction X.

In some embodiments, referring to FIG. 3, the display panel includes a substrate (not shown in the figure), and the first metal layer M1 and the capacitor metal layer MC are sequentially arranged away from the substrate. The first metal layer M1 is located between the substrate and the capacitor metal layer MC. The first conductive portion 11 is located at the side of the capacitor metal layer MC away from the first metal layer M1. For example, the side of the capacitor metal layer MC away from the first metal layer M1 includes at least one source-drain metal layer SD, and the first conductive portion 11 is located at least one source-drain metal layer SD.

The capacitor metal layer MC is located between the first metal layer M1 and the source-drain metal layer SD. An insulating layer is disposed between different metal layers. In addition, a semiconductor layer may be disposed between the first metal layer M1 and the substrate, and an insulating layer is disposed between the first metal layer M1 and the semiconductor layer.

Exemplarily, the first metal layer M1 includes a gate portion of a transistor. For example, in the display area, the first metal layer M1 includes a scanning signal line, a light-emitting control signal line, etc.

The capacitor metal layer MC includes an electrode plate of a capacitor and a reset signal line, etc. For example, in the display area, the capacitor metal layer MC includes an electrode plate of a storage capacitor of a pixel circuit and a reset signal line. The reset signal on the reset signal line is to reset the anode potential of the light-emitting element and/or the gate potential of the driving transistor in the pixel circuit.

The source-drain metal layer SD includes some signal traces. For example, in the display area, the source-drain metal layer SD includes data lines, etc.

In some embodiments, referring to FIGS. 1, 5 and 6 in combination, the first conductive portion 11 also includes a third segment 113, the second segment 112 is electrically connected to the first segment 111 and the third segment 113, and the third segment 113 is electrically connected to the second conductive portion 12. In the first direction X, the first segment 111 and the third segment 113 are located at the side of the second segment 112 away from the display area AA.

Exemplarily, the first segment 111 and the third segment 113 extend along the first direction X, and the second segment 112 extends along the second direction Y.

In this embodiment, since the third segment 113 is farther away from the display area AA, and the first end of the second conductive portion 12 is electrically connected to the third segment 113, it is equivalent to moving the first end of the second conductive portion 12 in a direction away from the display area, and the connection holes (for example, h1-h5) between the second conductive portion 12 and the first conductive portion 11 are moved in a direction away from the display area, so that the areas at both sides of the first functional area Q1 in the second direction Y can be used.

Exemplarily, referring to FIG. 5 and FIG. 4 for comparison, the wiring pattern in the trace area fanout2 in FIG. 5 is different from the wiring pattern in the trace area fanout2′ in FIG. 4, while the structures of other areas are the same. The height of the trace area fanout2′ in FIG. 4 in the first direction X is about 9500 μm, while the height of the trace area fanout2 in FIG. 5 in the first direction X can be compressed to about 4000 μm.

Exemplarily, referring to FIG. 1 and FIG. 5 in combination, in at least one first trace 1, in the second direction Y, the third segment 113 is closer to the edge of the display panel than the first functional area Q1 is. For example, at the first side of the first center line L1, the third segment 113 is closer to the first edge e1 than the third edge e3 is, and the connection holes h1-h5 are located between the third edge e3 and the first edge e1. At the second side of the first center line L1, the third segment 113 is closer to the second edge e2 than the fourth edge e4 is, and the connection holes h1-h5 are located between the fourth edge e4 and the second edge e2. In this way, the areas at both sides of the first functional area Q1 in the second direction Y are used as the trace area of the first trace 1.

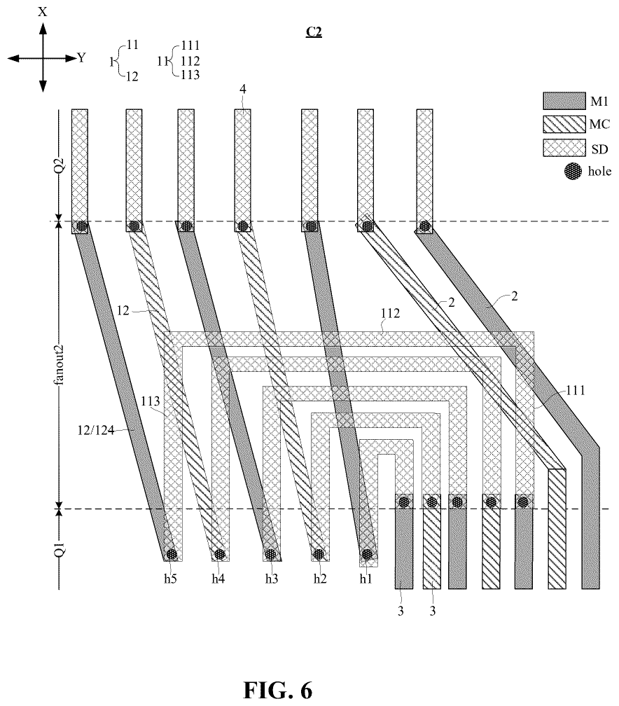

In some embodiments, as shown in FIG. 6, the first segment 111, the second segment 112, and the third segment 113 are located in the same film layer.

It is understandable that the first segment 111, the second segment 112, and the third segment 113 are located in different film layers from the second conductive portion 12. For example, as shown in FIG. 6, the first segment 111, the second segment 112, and the third segment 113 are located in the source-drain metal layer SD, some second conductive portions 12 are located in the first metal layer M1, and other second conductive portions 12 are located in the capacitor metal layer MC.

In this embodiment, the first segment 111, the second segment 112, and the third segment 113 are designed in the same film layer, and the first segment 111, the second segment 112, and the third segment 113 do not need to be connected through a connection hole, which can reduce the occupied space; in addition, the first segment 111, the second segment 112, and the third segment 113 can be prepared in an integrated manner to simplify the process.

In some embodiments, referring to FIGS. 1, 5 and 6 in combination, the second conductive portion 12 includes a fourth segment 124, the fourth segment 124 is electrically connected to the third segment 113, and the extension direction of the fourth segment 124 intersects with the extension direction of the third segment 113.

The fourth segment 124 and the third segment 113 are located in different film layers, and the fourth segment 124 and the third segment 113 are connected through a connection hole.

Exemplarily, the third segment 113 extends along the first direction X, and the extension direction of the fourth segment 124 intersects with both the first direction X and the second direction Y.

In other embodiments, referring to FIGS. 1, 7 and 8 for combination, the second conductive portion 12 includes a fourth segment 124 and a fifth segment 125, and the fourth segment 124 is electrically connected to the fifth segment 125 and the third segment 113. The fourth segment 123 and the third segment 113 have the same extension direction.

For example, the fourth segment 123 and the third segment 113 both extend along the first direction X, and the extension direction of the fifth segment 125 intersects with the extension direction of the fourth segment 124.

Exemplarily, the extension direction of the fifth segment 125 intersects with both the first direction X and the second direction Y.

In the same first trace 1, the fourth segment 124 and the fifth segment 125 are located in the same film layer, and the fourth segment 124 and the third segment 113 are located in different film layers. In the same first trace 1, the fourth segment 124 and the fifth segment 125 are a structure.

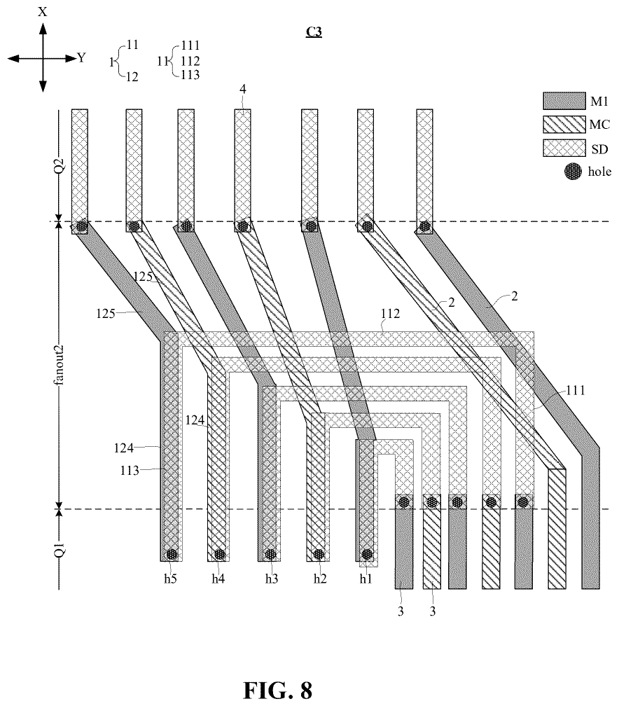

Exemplarily, as shown in FIG. 8, the orthographic projections of the third segment 113 and the fourth segment 124 on the plane where the display panel is located at least partially overlap. In this embodiment, in the thickness direction of the display panel, the third segment overlaps the fourth segment in design, and from the top view, this can reduce the area occupied by the first trace.

Exemplarily, the lengths of the third segment 113 and the fourth segment 124 in the first direction X are equal.

The examples shown in FIGS. 5 to 8 introduce that the connection holes between the first conductive portion and the second conductive portion are placed away from the display area by adding a third segment. In other examples, the connection holes between the first conductive portion and the second conductive portion can also be placed away from the display area by designing the extension direction of the second segment.

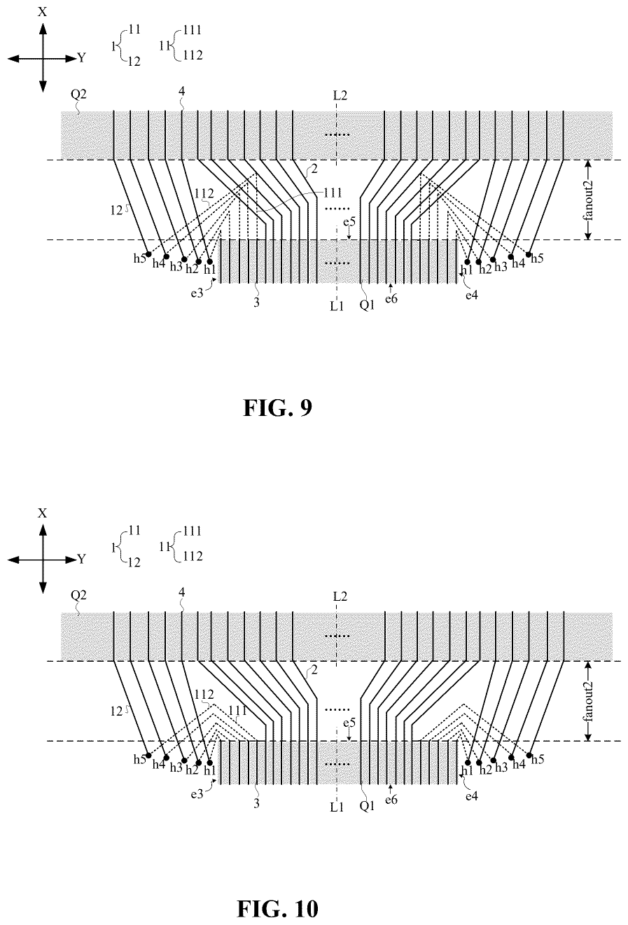

In some embodiments, referring to FIGS. 1 and 9 in combination, or referring to FIGS. 1 and 10 in combination, the first conductive portion 11 includes a first segment 111 and a second segment 112, the first end of the second segment 112 is electrically connected to the first segment 111, and the second end of the second segment 112 is electrically connected to the second conductive portion 12. From the first end of the second segment 112 to the second end of the second segment 112, the distance between the second segment 112 and the display area AA in the first direction X gradually increases.

As an example, as shown in FIG. 9, the first segment 111 extends along the first direction X, the extension direction of the second segment 112 intersects with both the first direction X and the second direction Y, and, from the first end of the second segment 112 to the second end of the second segment 112, the second segment 112 extends in a direction away from the second functional area Q2.

As another example, as shown in FIG. 10, the extension direction of the first segment 111 intersects both the first direction X and the second direction Y, and from the first end of the first segment 111 to the second end of the first segment 111, the first segment 111 extends in a direction away from the first center line L1. The first end of the first segment 111 is electrically connected to the third trace 3, and the second end of the first segment 111 is electrically connected to the second segment 112. In addition, the extension direction of the second segment 112 intersects both the first direction X and the second direction Y, and from the first end of the second segment 112 to the second end of the second segment 112, the second segment 112 extends in a direction away from the second functional area Q2.

Exemplarily, in the examples shown in FIG. 9 and FIG. 10, the first segment 111 and the second segment 112 are located in the same film layer.

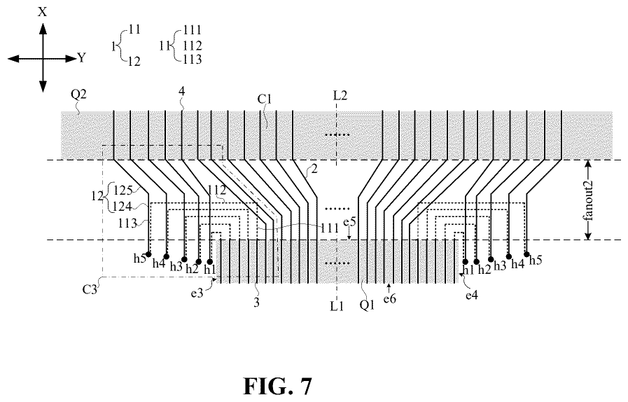

In some embodiments, referring to any one of FIG. 5, FIG. 7, FIG. 9 and FIG. 10, the first functional area Q1 includes a fifth edge e5, and the fifth edge e5 is an edge at the side of the first functional area Q1 facing the second functional area Q2. In the first direction X, first ends of at least part of the first conductive portions 11 are farther away from the second functional area Q2 than the fifth edge e5 is. The first ends of the first conductive portions 11 and the second conductive portions 12 are electrically connected through connection holes, that is, in the first direction X, at least one connection hole (for example, h1-h5) between the first conductive portion 11 and the second conductive portion 12 is farther away from the second functional area Q2 than the fifth edge e5 is. In this way, the areas at both sides of the first functional area Q1 in the second direction Y can be fully utilized.

Exemplarily, in the first direction X, the first ends of at least part of the first conductive portions 11 are located between the fifth edge e5 and the sixth edge e6, and the sixth edge e6 is an edge at the side of the first functional area Q1 away from the second functional area Q2.

In some embodiments, referring to any one of FIGS. 2 to 10, the trace area fanout2 also includes a second trace 2, and the second trace 2 is electrically connected to the output end of the first functional area Q1 and the input end of the second functional area Q2. The second trace 2 and the first trace 1 are electrically connected to different output ends of the first functional area Q1, and the second trace 2 and the first trace 1 are electrically connected to different input ends of the second functional area Q2.

In the second direction Y, the second trace 2 is closer to the first center line L1 of the first functional area Q1 than the second conductive portion 12 is.

Exemplarily, multiple first traces 1 and multiple third traces 3 of the first functional area Q1 are electrically connected in a one-to-one correspondence, and multiple second traces 2 and multiple third traces 3 of the first functional area Q1 are electrically connected in a one-to-one correspondence. In the second direction Y, the third traces 3 electrically connected to the first traces 1 are located at both sides of the third traces 3 electrically connected to the second traces 2. In other words, the second traces 2 are electrically connected to the third traces 3 in the middle area of the first functional area Q1, and the first traces 1 are electrically connected to the third traces 3 in the edge area of the first functional area Q1.

In this embodiment, only the first traces 1 connected to the third traces 3 in the edge area in the second direction Y are changed, which can facilitate the use of the areas at both sides of the first functional area Q1 to arrange at least part of the line segments of the first traces 1.

In some embodiments, as shown in FIGS. 3, 6 and 8, the second trace 2 and the first conductive portion 11 are located in different film layers. In this way, even if the first conductive portion 11 and the second line 2 intersect, the signals of the two may not crosstalk.

In some embodiments, as shown in FIG. 3, FIG. 6 and FIG. 8, adjacent second traces 2 are located in different film layers, and/or adjacent second conductive portions 12 are located in different film layers. In this way, signal interference between adjacent traces can be reduced.

For example, multiple second conductive portions 12 arranged in the second direction Y alternately occupy the first metal layer M1 and the capacitor metal layer MC, and/or multiple second traces 2 arranged in the second direction Y alternately occupy the first metal layer M1 and the capacitor metal layer MC.

Exemplarily, adjacent second conductive portions 12 and second traces 2 are located in different film layers.

In some embodiments, the first functional area includes the first output end to the n-th output end that are sequentially closer and closer to the first center line of the first functional area, and the first center line is at the same distance from the two edges of the first functional area in the second direction; the second functional area includes the first input end to the n-th input end that are sequentially closer and closer to the second center line of the second functional area, and the second center line is at the same distance from the two edges of the second functional area in the second direction; the output ends and the input ends are electrically connected through the first traces; the first output end to the n-th output end are sequentially connected to from the first input end to the n-th input end.

As shown in FIG. 2, the first functional area Q1 includes a plurality of third traces 3 arranged in the second direction Y, the second ends of the third traces 3 are electrically connected to the first ends of the first conductive portions 11, and the second ends of the third traces 3 serves as the output end of the first functional area Q1. In FIG. 2, taking an example that both sides of the first center line L1 are provided with eight (i.e., n is 8) first traces 1 respectively, at the first side of the first center line L1, the first third trace 3(1) to the eighth third trace 3(8) are sequentially arranged closer and closer to the first center line L1; and at the second side of the first center line L1, the first third trace 3(1) to the eighth third trace 3(8) are sequentially arranged closer and closer to the first center line L1.

The second functional area Q2 includes a plurality of fourth traces 4 arranged in the second direction Y, the first ends of the fourth traces 4 are electrically connected to the second ends of the second conductive portions 12, and the first ends of the fourth traces 4 serves as the input end of the second functional area Q2. At the first side of the second center line L2, the first fourth trace 4(1) to the eighth fourth trace 4(8) are sequentially arranged closer and closer to the second center line L2; and, at the second side of the second center line L2, the first fourth trace 4(1) to the eighth fourth trace 4(8) are sequentially arranged closer and closer to the second center line L2.

The first third trace 3(1) to the eighth third trace 3(8) at the first side of the first center line L1 and the first fourth trace 4(1) to the eighth fourth trace 4(8) at the first side of the second center line L2 are sequentially connected. In other words, the first third trace 3(1) at the first side of the first center line L1 is electrically connected to the first fourth trace 4(1) at the first side of the second center line L2, the second third trace 3(2) at the first side of the first center line L1 is electrically connected to the second fourth trace 4(2) at the first side of the second center line L2, and so on, the eighth third trace 3(8) at the first side of the first center line L1 is electrically connected to the eighth fourth trace 4(8) at the first side of the second center line L2.

The first third trace 3(1) to the eighth third trace 3(8) at the second side of the first center line L1 and the first fourth trace 4(1) to the eighth fourth trace 4(8) at the second side of the second center line L2 are connected in sequence. In other words, the first third trace 3(1) at the second side of the first center line L1 is electrically connected to the first fourth trace 4(1) at the second side of the second center line L2, the second third trace 3(2) at the second side of the first center line L1 is electrically connected to the second fourth trace 4(2) at the second side of the second center line L2, and so on, the eighth third trace 3(8) at the second side of the first center line L1 is electrically connected to the eighth fourth trace 4(8) at the second side of the second center line L2.

Exemplarily, the first center line L1 and the second center line L2 are on the same straight line.

In the present application, the first side of the first center line L1 and the first side of the second center line L2 are the same side (for example, both are the left side), and the second side of the first center line L1 and the second side of the second center line L2 are the same side (for example, both are the right side).

In some embodiments, when multiple third traces are electrically connected to multiple fourth traces in sequence through multiple first traces, as shown in FIG. 2, the first conductive portion 11 includes a first segment 111 and a second segment 112 electrically connected to each other, and the second segment 112 is electrically connected between the first segment 111 and the second conductive portion 12. In the first direction, the second segments electrically connected to from the first output end to the n-th output end are sequentially arranged closer and closer to the second functional area, and the lengths of the second segments electrically connected to from the first output end to the n-th output end gradually decrease.

In FIG. 2, taking n as 8 as an example, taking the first side of the first center line L1 as an example, the first third trace 3(1) to the eighth third trace 3(8) are electrically connected to the first first conductive portion 11 to the eighth first conductive portion 11 in sequence, wherein the connection holes h1-h8 are electrically connected to the first first conductive portion 11 to the eighth first conductive portion 11 in sequence, and the second segments 112 of the first first conductive portion 11 to the eighth first conductive portion 11 are sequentially arranged closer and closer to the second functional area Q2, and the lengths of the second segments 112 of the first first conductive portion 11 to the eighth first conductive portion 11 gradually decrease. In this embodiment, while avoiding the intersections of the multiple second conductive portions, the multiple third traces can be electrically connected to the multiple fourth traces in sequence through the multiple first traces.

In some embodiments, the first functional area includes a first output end to an n-th output end that are sequentially closer and closer to a first center line of the first functional area, and the first center line is at the same distance from two edges of the first functional area in the second direction; the second functional area includes a first input end to an n-th input end that are sequentially closer and closer to a second center line of the second functional area, and the second center line is at the same distance from two edges of the second functional area in the second direction; the output ends and the input ends are electrically connected through the first traces; the first output end to the n-th output end are sequentially connected to the n-th input end to the first input end.

As shown in FIG. 5, the first functional area Q1 includes a plurality of third traces 3 arranged in the second direction Y, the second ends of the third traces 3 are electrically connected to the first ends of the first conductive portions 11, and the second ends of the third traces 3 serves as the output end of the first functional area Q1. In FIG. 5, taking an example that both sides of the first center line L1 are provided with 5 (i.e., n is 5) first traces 1 respectively, at the first side of the first center line L1, the first third trace 3(1) to the fifth third trace 3(5) are sequentially arranged closer and closer to the first center line L1; and, at the second side of the first center line L1, the first third trace 3(1) to the fifth third trace 3(5) are sequentially arranged closer and closer to the first center line L1.

The second functional area Q2 includes a plurality of fourth traces 4 arranged in the second direction Y, the first ends of the fourth traces 4 are electrically connected to the second ends of the second conductive portions 12, and the first ends of the fourth traces 4 serves as the input end of the second functional area Q2. At the first side of the second center line L2, the first fourth trace 4(1) to the fifth fourth trace 4(5) are sequentially arranged closer and closer to the second center line L2; and, at the second side of the second center line L2, the first fourth trace 4(1) to the fifth fourth trace 4(5) are sequentially arranged closer and closer to the second center line L2.

The first third trace 3(1) to the fifth third trace 3(5) at the first side of the first center line L1 and the fifth fourth trace 4(5) to the first fourth trace 4(1) at the first side of the second center line L2 are electrically connected in sequence. In other words, the first third trace 3(1) at the first side of the first center line L1 is electrically connected to the fifth fourth trace 4(5) at the first side of the second center line L2, the second third trace 3(2) at the first side of the first center line L1 is electrically connected to the fourth fourth trace 4(4) at the first side of the second center line L2, and so on, the fifth third trace 3(5) at the first side of the first center line L1 is electrically connected to the first fourth trace 4(1) at the first side of the second center line L2.

The first third trace 3(1) to the fifth third trace 3(5) at the second side of the first center line L1 and the fifth fourth trace 4(5) to the first fourth trace 4(1) at the second side of the second center line L2 are electrically connected in sequence. In other words, the first third trace 3(1) at the second side of the first center line L1 is electrically connected to the fifth fourth trace 4(5) at the second side of the second center line L2, the second third trace 3(2) at the second side of the first center line L1 is electrically connected to the fourth fourth trace 4(4) at the second side of the second center line L2, and so on, the fifth third trace 3(5) at the second side of the first center line L1 is electrically connected to the first fourth trace 4(1) at the second side of the second center line L2.

It is understandable that, in the example shown in FIG. 5, multiple third traces are electrically connected to multiple fourth traces in reverse order through multiple first traces.

In some embodiments, when multiple third traces are electrically connected to multiple fourth traces in reverse order through multiple first traces, as shown in FIG. 5, the first conductive portion 11 includes a first segment 111 and a second segment 112 electrically connected to each other, and the second segment 112 is electrically connected between the first segment 111 and the second conductive portion 12. In the first direction, the second segments electrically connected to from the first output end to the n-th output end are sequentially arranged closer and closer to the second functional area, and the lengths of the second segments electrically connected to from the first output end to the n-th output end gradually increase.

In FIG. 5, taking n as 5 as an example, taking the first side of the first center line L1 as an example, the first third trace 3(1) to the fifth third trace 3(5) are electrically connected to the first first conductive portion 11 to the fifth first conductive portion 11 in sequence, wherein the connection holes h1 to h5 are electrically connected to the first first conductive portion 11 to the fifth first conductive portion 11 in sequence, and the second segments 112 of the first first conductive portion 11 to the fifth first conductive portion 11 are arranged sequentially closer and closer to the second functional area Q2, and the lengths of the second segments 112 of the first first conductive portion 11 to the fifth first conductive portion 11 gradually increase. In this embodiment, while avoiding the intersections of the multiple second conductive portions, the multiple third traces can be electrically connected to the multiple fourth traces in reverse order through the multiple first traces.

In some embodiments, the material impedance of the film layer where the first conductive portion 11 is located is less than the material impedance of the film layer where the second conductive portion 12 is located.

For example, the impedance of the first conductive portion 11 per unit length is less than the impedance of the second conductive portion 12 per unit length.

The second conductive portion 12 is disposed in the first trace, which is equivalent to adopting a winding design method to move the signal access end of the second conductive portion 12 to the side of the first functional area Q1 close to the first edge e1, or to move the signal access end of the second conductive portion 12 to the side of the first functional area Q1 close to the second edge e2, that is, the total length of the first trace may increase. In this embodiment, the material impedance of the film layer where the second conductive portion 12 is located is relatively small, so the impedance of the second conductive portion 12 may be relatively small, and the impedance of the first trace may not increase much as a whole.

In some embodiments, the film layer where the first conductive portion 11 is located is located at the side of the film layer where the second conductive portion 12 is located close to the light-emitting surface of the display panel.

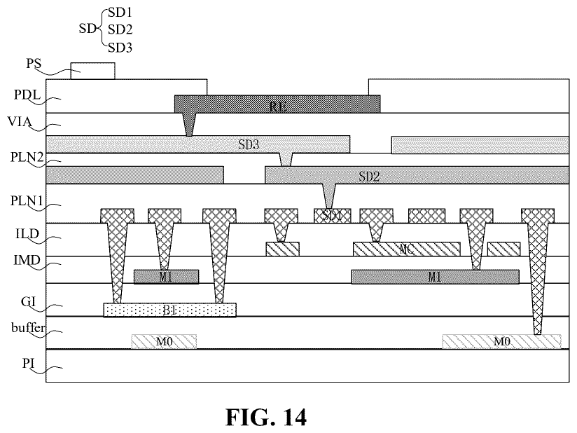

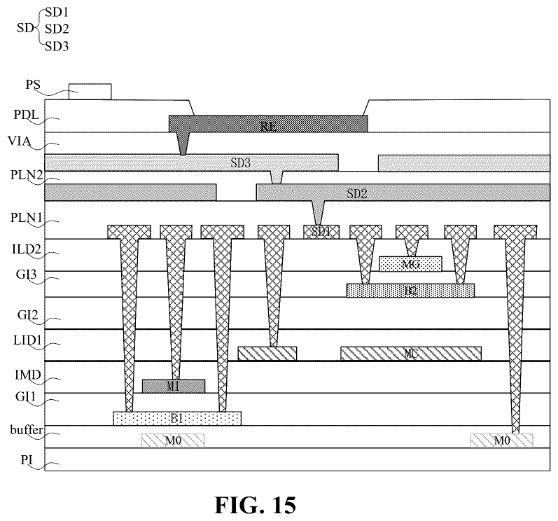

For example, the first conductive portion 11 is located in the source-drain metal layer SD, some second conductive portions 12 are located in the first metal layer M1, and other second conductive portions 12 are located in the capacitor metal layer MC, and the source-drain metal layer SD is closer to the light-emitting surface of the display panel than the first metal layer M1 and the capacitor metal layer MC are. Exemplarily, as shown in FIG. 14, the display panel is a low temperature polysilicon (LTPS) type display panel, or, as shown in FIG. 15, the display panel is a low temperature polycrystalline oxide (LTPO) type display panel. The source-drain metal layer SD includes a first source-drain metal layer SD1, a second source-drain metal layer SD2, and a third source-drain metal layer SD3, and the first conductive portion 11 is located in any one of the first source-drain metal layer SD1 and the second source-drain metal layer SD2.

In some embodiments, the line widths of the first conductive portions 11 in at least two first traces 1 are different. For example, when the lengths of the first conductive portions 11 are relatively long, the line widths of the first conductive portions 11 can be increased to balance the impedance difference of different first traces 1 and avoid relatively large impedance jumps of adjacent first traces.

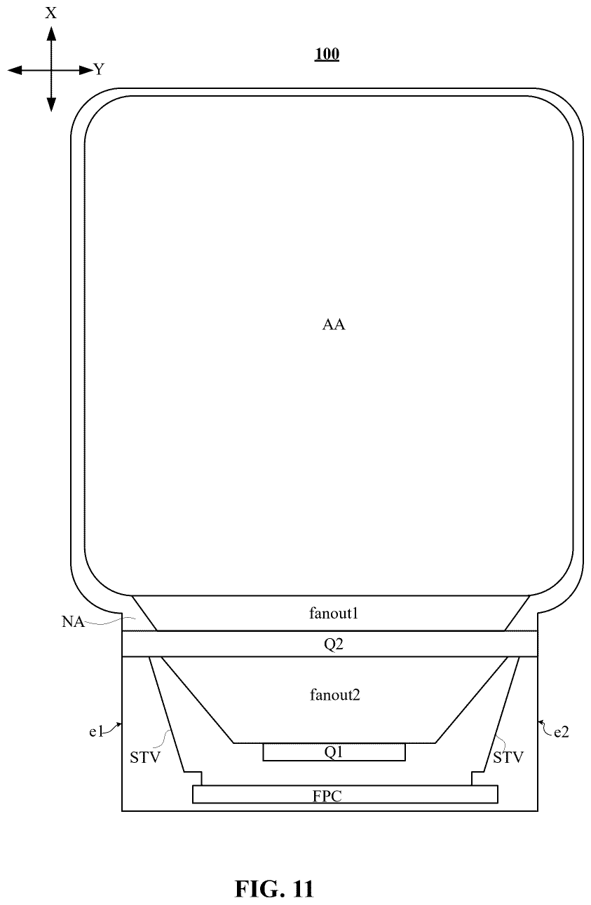

In some embodiments, as shown in FIG. 11, the display panel further includes a trigger signal line STV, the trigger signal line STV is electrically connected to a gate driving circuit (not shown in figure) of the display panel, and the trigger signal output by the driver chip IC is transmitted to the gate driving circuit through the trigger signal line STV, so as to trigger the gate driving circuit to work.

In the second direction Y, the trigger signal lines STV are closer to the edges of the display panel than the first traces in the trace area fanout2 are. For example, one of the trigger signal lines STV is closer to the first edge e1 of the display panel than the first traces in the trace area fanout2 are, and the other trigger signal line STV is closer to the second edge e2 of the display panel than the first traces in the trace area fanout2 are.

In this embodiment, the conflict between the first trace in the trace area fanout2 and the trigger signal line STV can be avoided, and the signal crosstalk between the two can be avoided.

Exemplarily, the display panel also includes a clock signal line, a reset signal line, a high-level signal line, a low-level signal line, etc. which are electrically connected to the gate driving circuit. In the second direction, the clock signal line, the reset signal line, the high-level signal line, the low-level signal line, etc. are all closer to the edges of the display panel than the first traces in the trace area fanout2 are.

In some embodiments, the second functional area Q2 is a bending area. The bending area can also be called a Bending area. The second functional area Q2 can be bent, and the structure on the side of the second functional area Q2 away from the display area AA can be bent to the back of the display panel to achieve a narrower bezel design. The ends of the fourth traces 4 of the second functional area Q2 serve as the input end of the second functional area Q2.

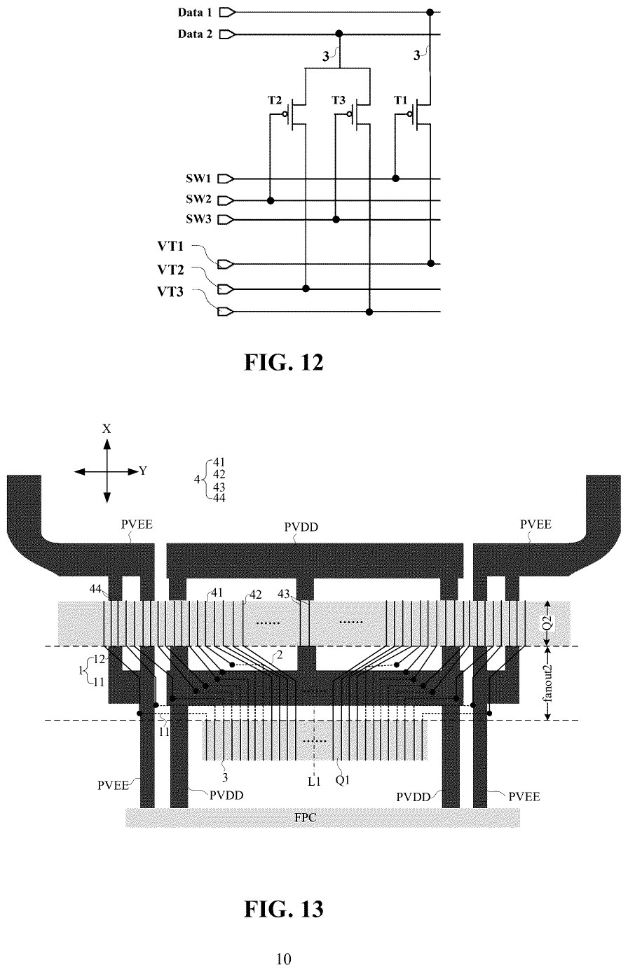

In some embodiments, the first functional area Q1 is a test area. The test area can also be called a Shorting bar area. A test circuit is disposed in the first functional area Q1. As an example, as shown in FIG. 12, the test circuit includes a first transistor T1, a second transistor T2, and a third transistor T3. The data line includes a first data line Data 1 and a second data line Data2. The first data line Data1 is electrically connected to the first electrode of the first transistor T1 through the third trace 3, and the second electrode of the first transistor T1 is electrically connected to the first test end VT1. The second data line Data2 is electrically connected to the first electrode of the second transistor T2 through the third trace 3, and the second electrode of the second transistor T2 is connected to the second test end VT2, or the second data line Data2 is electrically connected to the first electrode of the third transistor T3 through the third trace 3, and the second electrode of the third transistor T3 is electrically connected to the third test end VT3. In addition, the gate of the first transistor T1 is electrically connected to the first control signal end SW1, the gate of the second transistor T2 is electrically connected to the second control signal end SW2, and the gate of the third transistor T3 is electrically connected to the third control signal end SW3.

In this case, in the display area, the first data line Data1 can be a data line for controlling green sub-pixels, and the second data line Data2 can be a data line for controlling blue sub-pixels or red sub-pixels.

It can be understood that part of the data lines are electrically connected to the third trace by electrically connecting the first trace, and another part of the data lines are electrically connected to the third trace through the second trace. The first data line Data1 and the third trace are electrically connected with the first trace or the second trace therebetween, and the second data line Data2 and the third trace are electrically connected with the first trace or the second trace therebetween.

When the display panel is VT tested, the signal at the test signal end is transmitted to the data line through the transistor, and all sub-pixels displaying the same color are short-circuited together, thereby displaying a monochrome picture.

In some embodiments, as shown in FIG. 13, the display panel also includes a first power line PVDD and a second power line PVEE. The first power line PVDD is to transmit a positive voltage signal, and the second power line PVEE is to transmit a negative voltage signal. Exemplarily, the sub-pixel in the display area includes a light-emitting element and a pixel driving circuit, the first electrode of the light-emitting element is electrically connected to the pixel driving circuit, the pixel driving circuit is also electrically connected to the first power line PVDD, and the second electrode of the light-emitting element is electrically connected to the second power line PVEE.

In the thickness direction of the display panel, the first power line PVDD and/or the second power line PVEE overlap at least part of the first trace 1. It is understandable that the first power line PVDD and/or the second power line PVEE and the first trace 1 are located in different film layers.

The display panel also includes a touch trace (not shown in the figure), the touch trace is to transmit touch signals. The voltage on the first power line PVDD and the second power line PVEE is usually fixed. When at least part of the first trace 1 overlaps the first power line PVDD and/or the second power line PVEE, the interference of the signal on the touch trace with the signal on the first trace can be reduced.

Exemplarily, the fourth trace 4 of the second functional area Q2 includes a first sub-line 41, a second sub-line 42, a third sub-line 43, and a fourth sub-line 44. The first sub-line 41 is electrically connected to the first trace 1 in a one-to-one correspondence. The second sub-line 42 is electrically connected to the second trace 2 in a one-to-one correspondence. The third trace 43 is electrically connected to the first power line PVDD outside the second functional area Q2, and the first power line PVDD outside the second functional area Q2 can be electrically connected to multiple third sub-lines 43. The fourth sub-line 44 is electrically connected to the second power line PVEE outside the second functional area Q2, and the second power line PVEE outside the second functional area Q2 can be electrically connected to multiple fourth sub-lines 44.

The line width of the first power line PVDD and the line width of the second power line PVEE are both greater than the line width of the first trace 1, the line width of the first power line PVDD and the line width of the second power line PVEE are both greater than the line width of the second trace 2, and the line width of the first power line PVDD and the line width of the second power line PVEE are both greater than the line width of the fourth trace 4.

In some embodiments, an inorganic material layer is disposed between the first power line PVDD and/or the second power line PVEE and the first conductive portion 11. Exemplarily, the material of the inorganic material layer includes silicon dioxide (SiO2) and/or silicon nitride (SiNx). The inorganic material layer can reduce the electrochemical corrosion between the first power line PVDD and/or the second power line PVEE and the first conductive portion 11.

In other examples, an organic material layer is included between the first power line PVDD and/or the second power line PVEE and the first conductive portion 11.

In some embodiments, the first power line PVDD and the second power line PVEE are located at the side of the first conductive portion 11 away from the substrate of the display panel.

As an example, the display panel is a low temperature polysilicon (LTPS) type display panel, and the film layer structure of the display panel is shown in FIG. 14, the first semiconductor layer B1 includes an active layer of a transistor, and the material of the first semiconductor layer B1 includes LTPS. The metal layer includes an auxiliary metal layer M0, a first metal layer M1, a capacitor metal layer MC, a source-drain metal layer SD, etc. The source-drain metal layer SD includes a first source-drain metal layer SD1, a second source-drain metal layer SD2, and a third source-drain metal layer SD3. The anode layer RE includes anodes of multiple light-emitting elements.

As another example, the display panel is a low temperature polycrystalline oxide (LTPO) type display panel. The film layer structure of the display panel is shown in FIG. 15, and the similarities between FIG. 15 and FIG. 14 are not repeated here. The differences include: the display panel also includes a second semiconductor layer B2 and a gate metal layer MG. The material of the first semiconductor layer B1 includes LTPS, and the material of the second semiconductor layer B2 includes indium gallium zinc oxide (IGZO). The carrier movement speed of the LTPS type transistor is faster, and the leakage current of the IGZO type transistor is smaller.

Exemplarily, the first conductive portion 11 is located in the first source-drain metal layer SD1, and the first power line PVDD and the second power line PVEE are located in the second source-drain metal layer SD2 and/or the third source-drain metal layer SD3.

It should be noted that the number of traces in each area in the drawings of the present application is only some examples and is not used to limit the present application.

The display panel provided in the embodiments of the present application can be used in various fields such as mobile phones, tablets, vehicles, and televisions, and is also used for folding and curling display products.

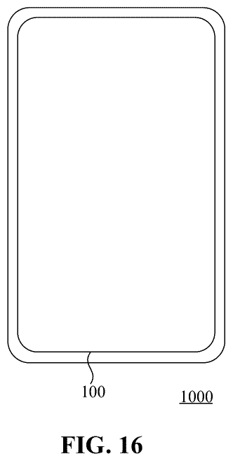

The present application also provides a display apparatus, including a display panel provided by the present application. Referring to FIG. 16, FIG. 16 is a schematic structural diagram of a display device provided by an embodiment of the present application. The display device 1000 provided in FIG. 16 includes a display panel 100 provided by any one of the above embodiments of the present application. The embodiment of FIG. 16 takes a mobile phone only as an example to illustrate the display device 1000. It can be understood that the display device provided by the embodiments of the present application can be a wearable product, a computer, a television, a car display device, and other display devices with display functions, which is not specially limited in the present application. The display device provided by the embodiments of the present application has the beneficial effects of the display panel provided by the embodiments of the present application. For details, referring to the specific description of the display panel in the above embodiments, the details are not repeated in this embodiment.

According to the embodiments of the present application as described above, these embodiments do not describe all the details, nor do they limit the application to only the specific embodiments described. Apparently, according to the above description, many modifications and changes can be made. These embodiments are selected and described in this specification in detail in order to better explain the principles and practical applications of the present application, so that technicians in the relevant technical field can make good use of the present application and the modified use based on the present application. The present application is limited only by the claims appended hereto along with their full scope and equivalents.

What is claimed is:

1. A display panel, comprising:
a display area and a non-display area, the non-display area comprising a first functional area, a trace area, and a second functional area which are sequentially closer and closer to the display area in a first direction;
the trace area comprising a plurality of first traces, at least part of the first traces each comprising a first conductive portion and a second conductive portion, a first end of the first conductive portion being electrically connected to an output end of the first functional area, a second end of the first conductive portion being electrically connected to a first end of the second conductive portion, a second end of the second conductive portion being electrically connected to an input end of the second functional area, and the first conductive portion and the second conductive portion being located in different film layers.

2. The display panel according to claim 1, wherein in a second direction, second ends of at least part of the first conductive portions are closer to an edge of the display panel than the first functional area is, and the first direction and the second direction intersect with each other.

3. The display panel according to claim 2, wherein
the first conductive portion comprises at least a first segment and a second segment, the second segment is electrically connected between the first segment and the second conductive portion, and
in the second direction, in the same first trace, the first segment and the second segment are closer to a first center line of the first functional area than the second conductive portion is, and the first center line of the first functional area is at a same distance from two edges of the first functional area in the second direction.

4. The display panel according to claim 3, wherein the first segment and the second segment are located in a same film layer.

5. The display panel according to claim 2, wherein the display panel comprises a substrate, and a first metal layer and a capacitor metal layer that are sequentially away from the substrate, and the first conductive portion is located at a side of the capacitor metal layer away from the first metal layer.

6. The display panel according to claim 3, wherein the first conductive portion further comprises a third segment, the second segment is electrically connected to the first segment and the third segment, and the third segment is electrically connected to the second conductive portion; and
in the first direction, the first segment and the third segment are located at a side of the second segment away from the display area.

7. The display panel according to claim 6, wherein the first segment, the second segment and the third segment are located in a same film layer.

8. The display panel according to claim 6, wherein the second conductive portion comprises a fourth segment, and an extension direction of the fourth segment intersects an extension direction of the third segment.

9. The display panel according to claim 6, wherein the second conductive portion comprises a fourth segment and a fifth segment, and the fourth segment is electrically connected between the fifth segment and the third segment; and
the fourth segment and the third segment have a same extension direction.

10. The display panel according to claim 9, wherein orthographic projections of the fourth segment and the third segment on a plane where the display panel is located at least partially overlap.

11. The display panel according to claim 2, wherein in the first direction, first ends of at least part of the first conductive portions are farther away from the second functional area than a fifth edge of the first functional area is, and the fifth edge is an edge at a side of the first functional area facing the second functional area.

12. The display panel according to claim 1, wherein the trace area further comprises a second trace, and the second trace is electrically connected to the output end of the first functional area and the input end of the second functional area; and
in the second direction, the second trace is closer to a first center line of the first functional area than the second conductive portion is, and the first center line is at a same distance from two edges of the first functional area in the second direction.

13. The display panel according to claim 12, wherein the second trace and the first conductive portion are located in different film layers.

14. The display panel according to claim 13, wherein the adjacent second traces are located in different film layers, or the adjacent second conductive portions are located in different film layers.

15. The display panel according to claim 1, wherein the first functional area comprises the first output end to the n-th output end that are sequentially closer and closer to a first center line of the first functional area, and the first center line is at a same distance from two edges of the first functional area in the second direction;
the second functional area comprises the first input end to the n-th input end that are sequentially closer and closer to a second center line of the second functional area, and the second center line is at a same distance from two edges of the second functional area in the second direction;
the output ends and the input ends are electrically connected through the first traces;
the first output end to the n-th output end are connected to the first input end to the n-th input end, respectively.

16. The display panel according to claim 15, wherein the first conductive portion comprises a first segment and a second segment that are electrically connected to each other, and the second segment is electrically connected between the first segment and the second conductive portion; and
in the first direction, the second segments electrically connected to from the first output end to the n-th output end are sequentially arranged closer and closer to the second functional area, and lengths of the second segments electrically connected to from the first output end to the n-th output end gradually decrease.

17. The display panel according to claim 1, wherein the first functional area comprises the first output end to the n-th output end that are sequentially closer and closer to a first center line of the first functional area, and the first center line is at a same distance from two edges of the first functional area in the second direction;
the second functional area comprises the first input end to the n-th input end that are sequentially closer and closer to a second center line of the second functional area, and the second center line is at a same distance from two edges of the second functional area in the second direction;
the output ends and the input ends are electrically connected through the first traces; and
the first output end to the n-th output end connect the n-th input end to the first input end, respectively.

18. The display panel according to claim 17, wherein the first conductive portion comprises a first segment and a second segment that are electrically connected to each other, and the second segment is electrically connected between the first segment and the second conductive portion; and
in the first direction, the second segments electrically connected to from the first output end to the n-th output end are sequentially arranged closer and closer to the second functional area, and lengths of the second segments electrically connected to from the first output end to the n-th output end gradually increase.

19. The display panel according to claim 1, wherein a film layer where the first conductive portion is located is located at a side of a film layer where the second conductive portion is located close to a light-emitting surface of the display panel.

20. A display device, comprising a display panel comprising a display area and a non-display area, the non-display area comprising a first functional area, a trace area, and a second functional area which are sequentially closer and closer to the display area in a first direction; the trace area comprising a plurality of first traces, at least part of the first traces each comprising a first conductive portion and a second conductive portion, a first end of the first conductive portion being electrically connected to an output end of the first functional area, a second end of the first conductive portion being electrically connected to a first end of the second conductive portion, a second end of the second conductive portion being electrically connected to an input end of the second functional area, and the first conductive portion and the second conductive portion being located in different film layers.
